(19) United States
(12) Patent Application Publication
(10) Pub. No.: US 2026/0129766 A1
(43) Pub. Date: May 7, 2026

(54) METHOD OF FORMING A PATTERN FOR MICROELECTRONIC DEVICES

(71) Applicant: Oregon State University, Corvallis, OR (US)

(72) Inventors: Harish Subbaraman, Corvallis, OR (US); Boxin Zhang, Corvallis, OR (US); Lakshmi Prakasan, Corvallis, OR (US)

(73) Assignee: Oregon State University, Corvallis, OR (US)

(21) Appl. No.: 19/354,637

(22) Filed: Oct. 9, 2025

Related U.S. Application Data
(60) Provisional application No. 63/717,801, filed on Nov. 7, 2024.

(51) Int. Cl. H05K 3/12; H05K 3/00

(52) U.S. Cl. CPC H05K 3/125; H05K 3/0079; H05K 2203/0568; H05K 2203/0776

(57) ABSTRACT

A method of forming a patterned conductive film comprises preparing a wafer for deposition. The method includes forming at least a layer above a substrate and patterning a mask comprising a photoresist material on the layer, where the mask comprises a plurality of openings. A plasma jet printer is used to direct a print head assembly towards an opening within the plurality of openings, where the print head assembly comprises an ink dispenser comprising a nanoparticle module. Nanoparticles are deposited, where a first portion of the nanoparticles is formed on the layer, and a second portion of the nanoparticles is formed on an uppermost surface of the mask. The wafer is submerged into an aqueous solution and dissolving portions of the photoresist material in contact with the layer to dislocate the second portion of the nanoparticles and leave the first portion of the nanoparticles to form the patterned conductive film.

### CLAIM FOR PRIORITY

This application claims priority to U.S. Provisional Ser. No. 63/717,801, filed on Nov. 7, 2024, titled “METHOD OF FORMING A PATTERN FOR MICROELECTRONIC DEVICES,” which is incorporated by reference in its entirety for all purposes.

### STATEMENT OF GOVERNMENT INTEREST

This application is supported by The United States Air Force Laboratory under Contract No. FA8650-20-2-5506 U18050. The government has certain rights in the invention.

### BACKGROUND

Methods of integrating semiconductor devices on the same substrate can be challenging. As such, methods to form structures that can couple logic transistors and/or memory devices are desirable.

### BRIEF DESCRIPTION OF DRAWINGS

Material described herein is illustrated by way of example and not by way of limitation in accompanying figures. For simplicity and clarity of illustration, elements illustrated in figures are not necessarily drawn to scale. For example, dimensions of some elements may be exaggerated relative to other elements for clarity. Also, various physical features may be represented in their simplified “ideal” forms and geometries for clarity of discussion, but it is nevertheless to be understood that practical implementations may approximate illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among figures to indicate corresponding or analogous elements.

FIG. 1 illustrates a flow diagram for a method to form nanoscale conductive patterns, in at least one example.

FIG. 2A illustrates a cross-section of a wafer comprising at least two layers above a substrate, in at least one example.

FIG. 2B illustrates a cross section of the substrate in FIG. 2A where a top layer may include patterned structures or multiple materials within a single layer, in at least one example.

FIG. 2C illustrates a cross-section of the substrate in FIG. 2A following the formation of a photo resist mask.

FIG. 2D illustrates a cross-section of the structure in FIG. 2C following the process of exposing the photo-resist mask.

FIG. 3A is a plan view illustration of a patterned wafer, in at least one example.

FIG. 3B is a plan view illustration of a die within the patterned wafer, in at least one example.

FIG. 3C illustrates a cross-section, through a line A-A′, of a device portion of the die in FIG. 3B, in accordance with at least one example.

FIG. 3D is an enhanced cross-sectional illustration of an opening within structure in FIG. 3C, through a line A-A,′ in accordance with at least one example, sidewalls of opening 306 of mask 302 comprises a re-entrant profile.

FIG. 4A illustrates a cross-section of structure in FIG. 3C following a process to deposit nanoparticles, within a first opening in a mask, using a plasma jet printer, in accordance with at least one example.

FIG. 4B illustrates a cross-section of a deposition configuration in FIG. 4A following a process to deposit nanoparticles within a second opening in the device portion.

FIG. 4C illustrates a cross-section of a deposition configuration in FIG. 4B following a process to deposit nanoparticles within a final opening in the device portion, in accordance with at least one example.

FIG. 5A illustrates a cross-section of wafer produced in FIG. 4C following a process to submerge the wafer into an aqueous solution, in accordance with at least one example.

FIG. 5B illustrates a cross-section of the configuration in FIG. 5A following process to sonicate and remove the photoresist material from the wafer to form conductive patterns, in accordance with at least one example.

FIG. 6A illustrates a cross-section of wafer in FIG. 5B following process to form conductive patterns on top layer of the wafer, in accordance with at least one example.

FIG. 6B is a plan view illustration of a portion of wafer in FIG. 6A, illustrating design/structures of devices, in accordance with at least one example.

FIG. 7A illustrates a cross-section of a deposition configuration in FIG. 4A, following a process to deposit the first nanoparticle in a second opening, followed by a process to deposit a second nanoparticle on the first nanoparticle in the second opening, in accordance with at least one example.

FIG. 7B illustrates a cross-section of wafer in FIG. 7A following a process to sonicate and form a first pattern comprising first nanoparticle materials in a first location and a second pattern comprising dual conductive layers comprising two distinct nanoparticle materials in a second location, in accordance with at least one example.

FIG. 8A illustrates a cross-section of a deposition configuration in FIG. 4A, illustrating impact of flared resist on nanoparticle deposition, in accordance with at least one example.

FIG. 8B illustrates a cross-section of a deposition configuration in FIG. 8A, illustrating the effect of reducing height of print head from above mask on nanoparticle deposition, in accordance with at least one example.

FIG. 9 illustrates a cross-section of a deposition through an opening comprising a re-entrant profile, in accordance with at least one example.

FIG. 10A illustrates a configuration where nanoparticles are deposited through dual masks, in accordance with at least one example.

FIG. 10B illustrates a configuration where nanoparticles are deposited through dual masks, in accordance with at least one example.

FIG. 11 illustrates a flow diagram for method to form nanoscale conductive patterns using multi print heads, in accordance with at least one example.

FIG. 12A illustrates a cross-section of a deposition configuration where multiple print heads are utilized to simultaneously deposit nanoparticles within different openings, in accordance with at least one example.

FIG. 12B illustrates a cross-section of a deposition configuration in FIG. 12A following a process to deposit a second conductive layer within a selected opening, in accordance with at least one example.

FIG. 13A illustrates a cross-section of a deposition configuration in FIG. 12A illustrating the effect of depositing with multiple prints heads to simultaneously deposit nanoparticles within different openings, in accordance with at least one example.

FIG. 13B illustrates a cross-section of a deposition configuration in FIG. 13A, where implementing a shadow mask can prevent overlap of different nanoparticles during simultaneous deposition, in accordance with at least one example.

FIG. 14A is an isometric illustration of a deposition configuration illustrating an effect of implementing a shadow mask during simultaneous deposition of different nanoparticles using multiple print heads, in accordance with at least one example.

FIG. 14B is a cross-sectional illustration of a portion of a deposition configuration in FIG. 14A.

### DETAILED DESCRIPTION

At least one example describes deposition of conductive layers using plasma jet printer on a masked substrate. While at least one example is described with reference to conductive nanoparticle deposition, the deposition described herein can be used for any application where deposition of semiconductor material is desired. In at least one example, nanoparticle deposition can be used for fabricating interconnects, gates, source and drain contacts for semiconductor devices. Here, numerous specific details are set forth, such as structural schemes and detailed fabrication methods to provide a thorough understanding of examples of present disclosure. It will be apparent to one skilled in art that examples of present disclosure may be practiced without these specific details. In other instances, well-known features, such as process equipment and device operations, are described in lesser detail to not unnecessarily obscure examples of present disclosure. Furthermore, it is to be understood that examples shown in Figures are illustrative representations and are not necessarily drawn to scale.

In some instances, well-known methods and devices are shown in block diagram form, rather than in detail, to avoid obscuring at least one example. Reference throughout this specification to “an example,” “one example,” “in at least one example,” or “some examples” means that a particular feature, structure, function, or characteristic described in connection with example is included in at least one example. Thus, appearances of phrase “in an example,” “in at least one example,” or “in one example” or “some examples” in various places throughout this specification are not necessarily referring to same example of disclosure. Furthermore, particular features, structures, functions, or characteristics may be combined in any suitable manner in one or more examples. For example, a first example may be combined with a second example anywhere particular features, structures, functions, or characteristics associated with two examples are not mutually exclusive.

As used in herein, singular forms “a,” “an,” and “the” are intended to include plural forms as well, unless context clearly indicates otherwise. It will also be understood that term “and/or” as used herein refers to and encompasses all possible combinations of one or more of associated listed items.

Here, “coupled” and “connected,” along with their derivatives, may be used herein to describe functional or structural relationships between components. These terms are not intended as synonyms for each other. Rather, in particular examples, “connected” may be used to indicate that two or more elements are in direct physical, optical, or electrical contact with each other. “Coupled” may be used to indicated that two or more elements are in either direct or indirect (with other intervening elements between them) physical, electrical, or magnetic contact with each other, and/or that two or more elements co-operate or interact with each other (e.g., as in a cause-and-effect relationship).

Here, “over,” “under,” “between,” and “on” refer to a relative position of one component or material with respect to other components or materials where such physical relationships are noteworthy. For example, in context of materials, one material or material disposed over or under another may be directly in contact or may have one or more intervening materials. Moreover, one material disposed between two materials may be directly in contact with two layers or may have one or more intervening layers. In contrast, a first material “on” a second material is in direct contact with that second material. Similar distinctions are to be made in context of component assemblies. As used throughout this description and in claims, a list of items joined by term “at least one of” or “one or more of” can mean any combination of listed terms.

Here, “adjacent” generally refers to a position of a thing being next to (e.g., immediately next to or close to with one or more things between them) or adjoining another thing (e.g., abutting it).

Here, “device” may generally refer to an apparatus according to context of usage of that term. For example, a device may refer to a stack of layers or structures, a single structure or layer, a connection of various structures having active and/or passive elements, etc. Generally, a device is a three-dimensional structure with a plane along x-y direction and a height along z direction of an x-y-z Cartesian coordinate system. In at least one example, a plane of device may also be plane of an apparatus which comprises device.

Unless otherwise specified in explicit context of their use, terms “substantially equal,” “about equal,” and “approximately equal” mean that there is no more than incidental variation between two things so described. Such variation is typically no more than +/−10% of a predetermined target value.

Here, “left,” “right,” “front,” “back,” “top,” “bottom,” “over,” “under,” and similar terms are used for descriptive purposes and not necessarily for describing permanent relative positions. For example, terms “over,” “under,” “front side,” “back side,” “top,” “bottom,” “over,” “under,” and “on” as used herein refer to a relative position of one component, structure, or material with respect to other referenced components, structures, or materials within a device, where such physical relationships are noteworthy. These terms are employed herein for descriptive purposes only and predominantly within context of a device z-axis and therefore may be relative to an orientation of a device. Hence, a first material “over” a second material in context of a figure provided herein may also be “under” second material if device is oriented upside-down relative to context of figure provided. Similar distinctions are to be made in context of component assemblies.

Here, “between” may be employed in context of z-axis, x-axis, or y-axis of a device. A material that is between two other materials may be in contact with one or both of those materials. In another example, a material that is between two or other materials may be separated from both of the other two materials by one or more intervening materials. A material “between” two other materials may therefore be in contact with either of the other two materials. In another example, a material “between” two other materials may be coupled to the other two materials through an intervening material. A device that is between two other devices may be directly connected to one or both of those devices. In another example, a device that is between two other devices may be separated from both of the other two devices by one or more intervening devices.

Semiconductor fabrication processes are the backbone of modern electronics, underpinning production of a vast array of electronic devices that have become useful in everyday life. Traditional semiconductor fabrication involves plurality of sequence of operations, where each operation contributes to outcomes of the of the final product in terms of functionality, performance, and reliability. One of the processes in the plurality of sequence of operations is deposition, where thin films of various materials are deposited onto semiconductor substrates having unpatterned or patterned surfaces. Together patterning, deposition, and etch (or selective removal of material) forms over 80% of process operations in fabrication of electronic circuits, memory cells, sensors, and other semiconductor devices. Among the multitude of deposition techniques, plasma enhanced chemical vapor deposition (PECVD), atomic layer deposition (ALD), plasma enhanced atomic layer deposition (PEALD), and chemical vapor deposition (CVD) process. Other examples include sputtering and thermal evaporation which are examples of physical vapor deposition process, useful in semiconductor fabrication. PVD processes are not known to produce hazardous byproducts or employ hazardous gases.

In at least one example, sputtering provides exceptional control over film thickness, composition, and uniformity, making it highly versatile and suitable for a wide range of semiconductor applications. However, high vacuum conditions are typically required to ensure the purity and quality of the deposited films, necessitating sophisticated vacuum systems and increasing energy consumption and process complexity. On the other hand, thermal evaporation offers an alternative approach to depositing thin films onto substrates or on patterned features, particularly metals and certain organic materials. But thermal evaporation may provide limitations, such as depositing materials with relatively low vaporization temperatures.

While methods like sputtering and thermal evaporation may be attractive, it may be desirable to deposit multiple materials sequentially or simultaneously on a blanket or on patterned features of a single substrate. In at least one example, additive manufacturing or printing methods of material deposition has emerged over traditional deposition and patterning process. Such methods can be useful in terms of cost, increased throughput, and enhanced conformity. By selectively printing over designated areas, this technique can minimize multiple patterning process operations, conserve substantial material, and enable printing of diverse materials on the same layer within a single printing step. Printing techniques such as inkjet printing (IJP), aerosol jet printing (AJP), or Nscrypt may be utilized for material deposition in additive manufacturing. However, such techniques often require additional steps including thermal heating to evaporate solvents and fuse metallic nanoparticles to form a sufficiently contiguous layer of conductive film.

In at least one example, plasma jet printing (PJP), a cutting-edge additive manufacturing technique, may be implemented to replace traditional material deposition methods and overcome inkjet printing (IJP), aerosol jet printing (AJP), or Nscrypt printing techniques. In at least one example, PJP may be implemented to create patterns on both rigid and flexible substrates. In at least one example, PJP utilizes inherent properties of plasma—ions, UV radiation, electrons, and free radicals—to not only modify the substrate surface but also promote self-sintering of deposited nanomaterials. However, to pattern small feature sizes (for example, features less than 10 microns across) PJP deposition process may be implemented using lithographically patterned masks that are formed on substrates. Depending on application, the mask may be formed on unpatterned or patterned features. In at least one example, masks may have features such re-entrant sidewalls that makes it useful for pattern fidelity as will be discussed below. In at least one example, masks may be patterned by 248 nm, 193 nm, and contact print lithography techniques. Thinner masks may be patterned by electron beam direct write lithography techniques. The patterned substrate may be placed in a chamber housing the plasma jet printer in a path of nanoparticles that exit from the printer.

In at least one example, a PJP deposition utilizes a dielectric barrier discharge plasma produced within a section of a print head of the PJP to transport ink containing nanoparticles towards the mask. In at least one example, the ink is deposited over a small region of the mask including an opening within the mask. In at least one example, after deposition the mask is removed and nanoparticles remaining on the substrate have a pattern defined by a shape of the mask opening. Unlike inkjet printing (IJP), aerosol jet printing (AJP), and Nscrypt printing techniques, no additional heating is required after PJP deposition. Avoiding additional heating may enable thinner masks (less than 100 nm thickness) to be implemented, where thinner masks can also reduce feature size and spacing between openings. Thinner masks may succumb to degradation in fine features due to heating.

Within the PJP, a dielectric barrier discharge plasma is produced using a high voltage power supply applied across two adjacent electrodes. The carrier gas and precursor gas are passed through the print head where they become ionized producing the plasma. In at least one example, the ink is stored in an ink dispenser which is coupled with a transport tube connected with a plasma chamber. In at least one example, the ink is transformed into a mist using an external ultrasonic transducer and is carried to the plasma chamber by the precursor gas. In at least one example, ink containing the nanoparticles is carried out by the gas and ionized particles exiting the plasma (and print head) and deposited over a selected area on a patterned substrate. In at least one example, a steady deposition of nanoparticles over a period forms a layer of conductive material. The deposition process may be sequential where each opening, collection, or small collections of openings are printed or deposited at a time. Depending on the application, one or more layers of conductive materials can be deposited into each opening by reprinting or redeposition. When using multiple print heads to deposit multiple openings simultaneously, filters may be used to prevent cross contamination of nanoparticles due to diffusion. Such filters may include openings that may be aligned with openings in the patterned substrate.

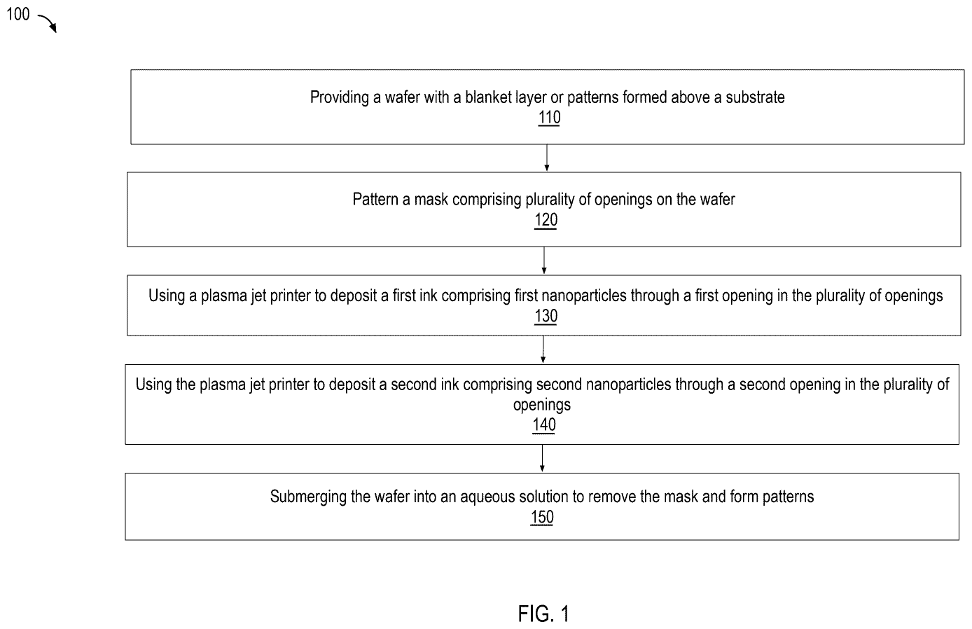

FIG. 1 illustrates a flow diagram for method 100 to fabricate a pattered conductive film in at least one example. In at least one example, method 100 begins at operation 110 providing a wafer with blanket layer or patterns formed above a substrate. Method 100 continues at operation 120 with patterning a mask comprising plurality of openings on a top layer of the wafer. In at least one example, method 100 continues at operation 130 by using a plasma jet printer to deposit a first ink comprising first nanoparticles through a first opening in the plurality of openings. In at least one example, method 100 continues at operation 140 by using the plasma jet printer to deposit a second ink comprising second nanoparticles through a second opening in the plurality of openings. In at least one example, method 100 concludes at operation 150 by submerging the wafer into an aqueous solution to remove the mask and form patterns comprising conductive materials. Depending on embodiments, the first ink and second ink can be same or different, and the first opening and second opening can be the same shape and size or be different. Other parameters such as materials of ink and methods of removal of mask will be discussed below.

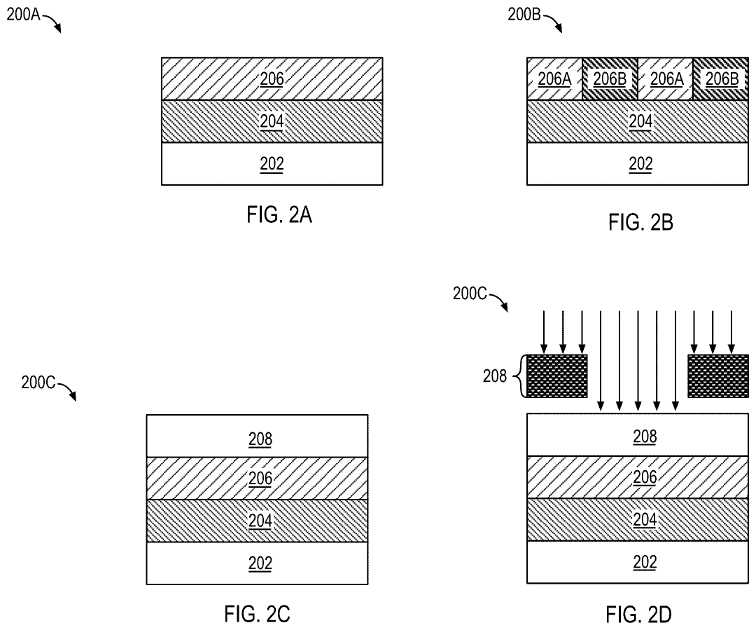

FIG. 2A illustrates a cross-section of a wafer 200A comprising at least two layers, in at least one example. In at least one example, wafer 200A comprises a substrate 202, a layer 204 on substrate 202, and a layer 206 on layer 204. In at least one example, substrate 202 can include rigid and flexible materials for example silicon, glass, polyimide, polymer, paper, or organic materials. Layer 204 can include a conductive material or a dielectric. In at least one example, layer 206 can include a conductive material or a dielectric.

FIG. 2B illustrates a cross section of a wafer 200B where layer 206 may include patterned structures or multiple materials within a single layer. In at least one example, layer 206 includes structure 206A adjacent to structure 206B, where structure 206A and structure 206B may include a conductive and an insulator material, respectively. In at least one example, structure 206A and structure 206B can include patterned structures with different devices or features. In at least one example, both layer 204 and layer 206 can include patterned structures. Methods of patterning above layer 206 are described below.

FIG. 2C illustrates a cross-section of a wafer 200C. In at least one example, wafer 200C is wafer 200A in FIG. 2A following the formation of a photoresist layer 208 on layer 206. In at least one example, photoresist layer 208 is formed on layer 206 by a lithographic process.

In at least one example, wafer 200A undergoes one or more cleaning operations with acetone, isopropyl alcohol (IPA), and deionized water (DI water). After drying wafer 200A using gaseous nitrogen, a wafer pre-bake may be performed. In at least one example, a wafer pre-bake may be carried out in at least 100 degrees Celsius, for at least 5 minutes. In at least one example, a resist primer is spun on layer 206 to promote adhesion between photoresist and layer 206. In at least one example, a photoresist layer 208 is spun on surface of layer 206. In at least one example, photoresist layer 208 can be spun onto layer 206 at 3000 rpm for 30 seconds. In at least one example, a post-baking operation is carried out where wafer 200A is heated to a temperature of at least 100 degrees Celsius for at least 3 minutes prior to exposure. In at least one example, photoresist layer 208 may comprise thickness between 50 nm and 2 microns depending on type of photoresist material, exposure conditions, and size of openings to be formed.

FIG. 2D illustrates a cross-section of wafer 200C in FIG. 2C following the process of exposing photoresist layer 208, in accordance with at least one example. Exposure wavelength can depend on type of photoresist material. In at least one example, exposure wavelength can vary between 193 nm for argon fluoride laser (ArF) and 248 nm for krypton fluoride (KrF) laser to pattern desired mask patterns to light expose photoresist layer 208. In at least one example, direct write lithography (DWL) process using UV light may be utilized to pattern desired mask patterns.

In at least one example, the mask formation process further involves immersion of the patterned substrate in the developer solution (MF321) and agitation for 1 minute. In at least one example, a rinse wafer is rinsed with DI water and dried using N₂ gas to form a patterned mask comprising a photoresist material on the wafer. In at least one example, a plasma etch may be performed to remove striations and stringers of photoresist material at the edges of the opening. Stringers can lead to delamination of conductive material from wafer during mask removal process in downstream processing.

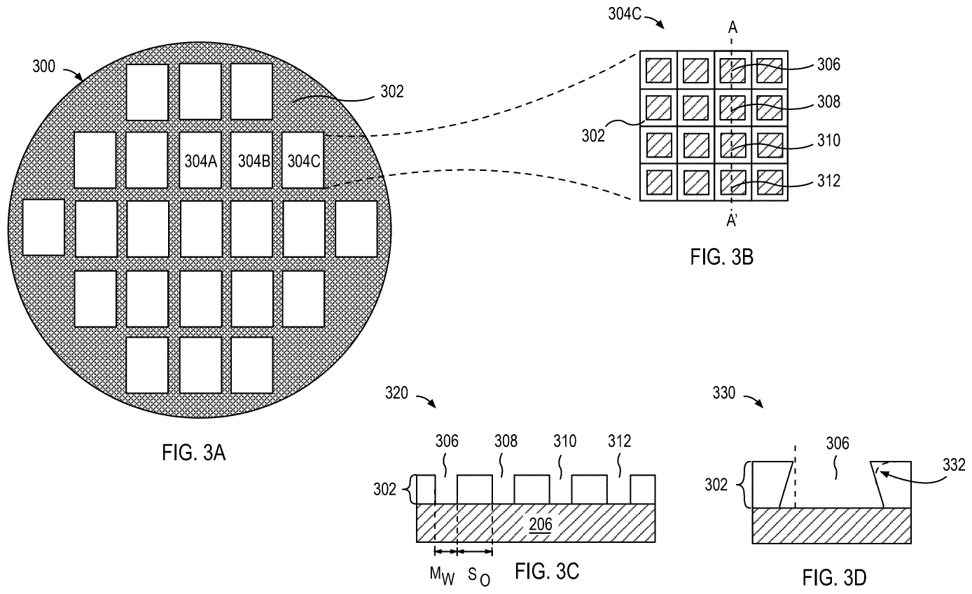

FIG. 3A is a plan view illustration of a wafer 300, in at least one example. In at least one example, wafer 300 includes a mask 302. In at least one example, mask 302 defines a pattern for a plurality of dies (for example die 304A, 304B, 304C, etc.), where each die comprises sub patterns. In at least one example, die 304A, die 304B, die 304C, etc., can be substantially identical. In other examples, die 304A may include a first set of test structures and die 304B may include a second set of test structures or patterns.

FIG. 3B is a plan view illustration of a die, such as die 304C defined by mask 302, in at least one example. In at least one example, die 304C comprises multiple openings 306, 308, 310, 312, etc. In at least one example, openings 306, 308, 310, 312, etc., comprise the same or substantially same size. In other examples, openings 306, 308, 310, 312, etc., can each comprise a different shape and/or a size. In at least one example, openings 306, 308, 310, 312, etc., are rectangles or squares as shown.

FIG. 3C illustrates a cross-section of a structure 320, in accordance with at least one example. Structure 320 is a portion of die 304C in FIG. 3B, through a line A-A′, in at least one example. In at least one example, mask 302 has a substantially vertical sidewall profiles. In at least one example, sidewalls may be tapered to increase at a base portion of mask 302. In at least one example, openings 306, 308, 310, and 312 have a substantially equal width M_{W}. In at least one example, the spacing S_{O} between adjacent openings may be substantially uniform or different. In at least one example, spacing S_{O} may be defined a-priory depending on a desired material or deposition parameters, as will be discussed below.

FIG. 3D illustrates a cross-section of a structure 330. Structure 330 is an enhanced cross-sectional illustration of opening 306 in FIG. 3B, through a line A-A′, where sidewalls of opening 306 of mask 302 comprises a re-entrant profile, in at least one example. In at least one example, a reentrant profile may be implemented to advantageously enable mask removal to form patterned structures, as discussed below. In at least one example, a re-entrant sidewall profile can be useful when the photoresist of mask 302 comprises a thickness of 100 nm or less. In at least one example, when a resist is less than 100 nm in thickness, and a combined thickness of nanoparticles to be deposited is 50 nm or less, it may be useful to have a re-entrant profile of opening 306, as discussed below. In at least one example, electron beam resist is a photoresist that is sensitive to electrons. The electron beam resist comprises chemical properties (molecular chain recombination) where exposed parts of the resist are altered after scanning by an electron beam. In at least one example, edges of opening 306 can be rounded as indicated by dashed lines 332.

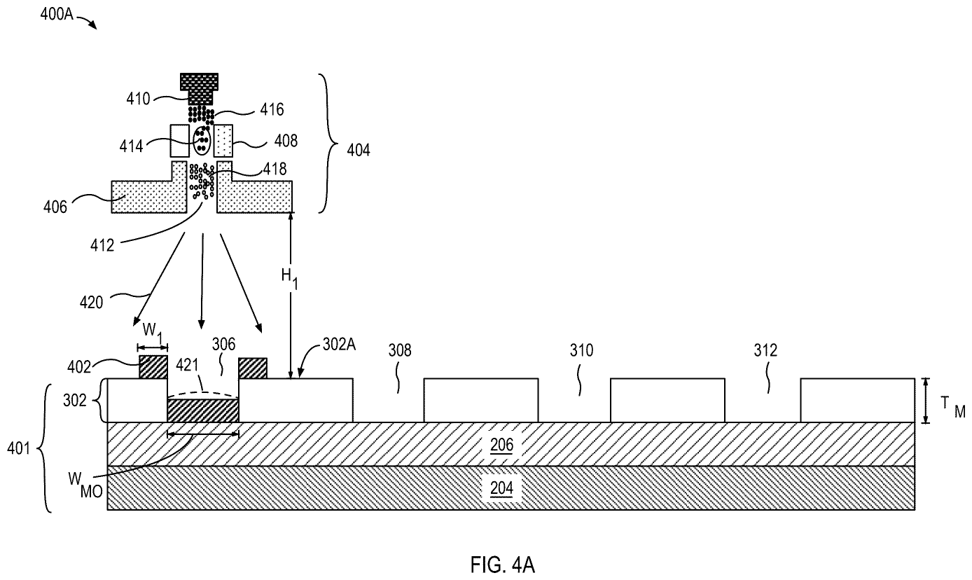

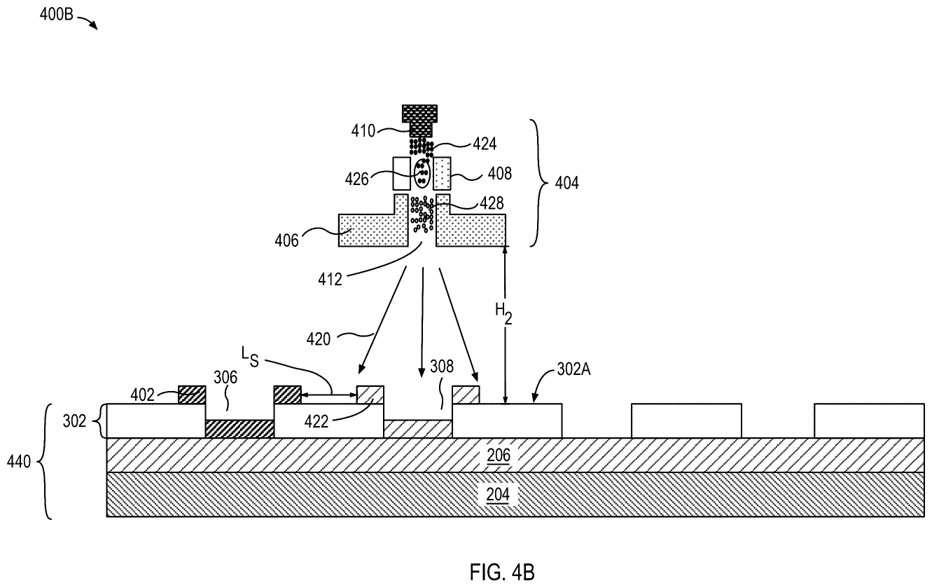

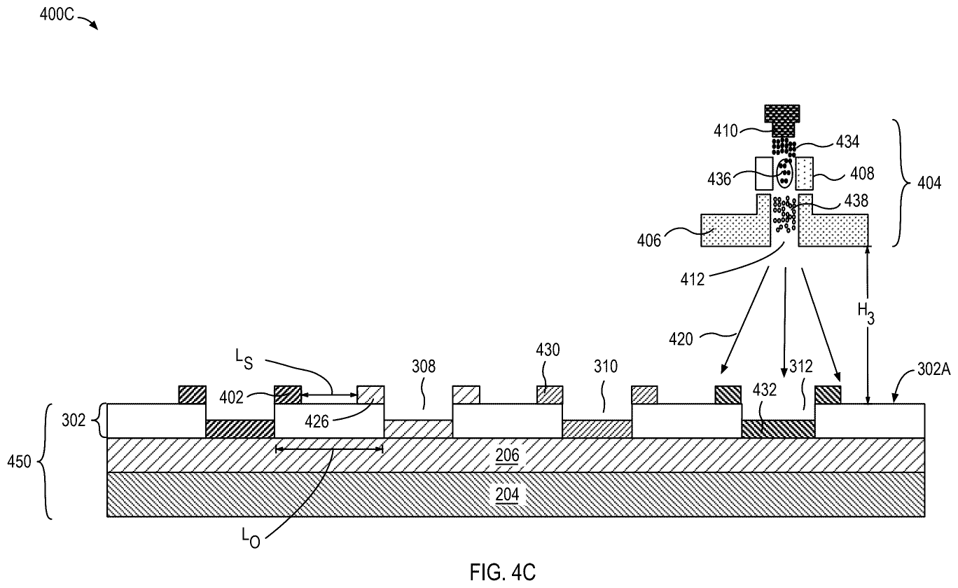

FIG. 4A illustrates a cross-section of a deposition configuration 400A. In at least one example, deposition configuration 400A illustrates structure 320 in FIG. 3C following a process to deposit a conductive material 402 within opening 306 on surface of layer 206 to form wafer 401. In at least one example, a plasma jet printer may be utilized to deposit conductive material 402, where the plasma jet printer comprises a print head assembly 404. In at least one example, the print head assembly 404 comprises a print head 406, a pair of electrodes 408, and an ink source 410.

In at least one example, within print head assembly 404, a dielectric barrier discharge plasma is produced by using a high voltage power supply (not shown) that is coupled with applied pair of electrodes 408. In at least one example, a carrier gas and precursor gas are passed through the pair of electrodes 408 where they become ionized producing a plasma 414. In at least one example, ink within ink source 410 is transformed into a mist 416 using an external ultrasonic transducer and is directed to plasma 414. In at least one example, an electromagnetic field that generates plasma 414 accelerates nanoparticles, within mist 416, towards the print head 406. In at least one example, when mist 416 passes through plasma 414, the reactive ionic species, electrons, and free radicals generated in plasma 414 interact with nanoparticles within mist 416. In at least one example, species within plasma 414 is directly controlled by chemical make-up of carrier gas and precursor gas. By changing the chemical make-up of carrier gas and precursor gas chemical reactions between mist 416 and species with plasma the electronic properties of the mist 416 can be modified.

In at least one example, ink comprising gold or silver nanoparticles can be utilized for deposition. In at least one example, the ink is diluted with de-ionized (DI) water, with a ratio of ink: DI water of least 1:10, and supplemented with 20-30% of propylene glycol before dilution. In at least one example, prior to transforming into a mist the ink can undergo a sonication process, where the sonication process can last for up to 15 minutes.

In at least one example, the print head 406 comprises at least one opening 412 for nanoparticles 418 to exit print head 406. In at least one example, nanoparticles 418 exit the plasma and pass through opening 412 in print head 406 and diffuse, due to an absence of fields within print head 406 or in presence of weak stray electromagnetic fields away from electrode 408. In at least one example, nanoparticles 418 are directed towards mask 302 and opening 306 towards surface of layer 206. A large collection of nanoparticles 418 may be deposited on portions of mask 302 and on layer 206 to form conductive material 402 that is at least contiguous within opening 306. In at least one example, nanoparticles 418 deposited on mask 302 span a width W₁. In at least one example, the width W₁ may be determined by a height H₁ of print head assembly 404 above surface 302A of mask 302. In at least one example, height H₁ can be up to 10 mm and width W₁ can be up to 10 microns. In at least one example, lateral diffusion (indicated by arrows 420) of nanoparticles 418 through opening 412 is determined by height H₁ and may be tuned, as discussed below. In at least one example, the profile of conductive material 402 formed at top edges of opening 306 (on top of mask 302) may be different from that formed within a base of opening 306. In at least one example, conductive material 402 formed on layer 206 may have a substantially flat top surface as shown. In at least one example, conductive material 402 formed on layer 206 may have a center high profile as indicated by dashed lines 421. In other examples, conductive material 402 may not be in contact with inner sidewalls of mask 302 within opening 306. In at least one example, if sidewalls of mask 302 within opening 306 are tapered (to decrease with height away from surface of layer 206), then some nanoparticles 418 may be deposited on inner sidewalls. In at least one example, width W_{MO} can be up to several hundred microns such as 300-500 microns. In at least one example, width W_{MO} can be sub-micron such as between 100 nm to 250 nm.

In at least one example, interaction between plasma 414 and mist 416 is a dry process and aids in depositing a film comprising nanoparticles 418 on surface of layer 206 that may be devoid of wet chemicals. In at least one example, no additional heating is performed post deposition to evaporate any aqueous matter and coalesce nanoparticles. Avoiding heating can reduce or eliminate contraction of photoresist material in mask 302. In at least one example, adhesion and differential contraction between mask 302 and conductive material 402 formed on mask 302 can cause modification in mask 302 through alteration in shape and size of adjacent opening 308. In at least one example, alteration of mask openings may adversely affect deposition profile as well as removal of mask 302. Heating post deposition can also cause conductive material 402 to coalesce to mask 302, affect clean removal, and reduce patterning fidelity. In at least one example, when mask 302 has a thickness T_{M} of less than 100 nm, heating post deposition can cause inner sidewalls of mask 302 to lose structural integrity, fusing portions of conductive material 402 deposited on top of mask 302 with portion of conductive material 402 deposited on layer 206. In at least one example, fusing can present problems during removal of mask 302.

In at least one example, nanoparticle species deposited are contained within an ink in ink source 410. In at least one example, nanoparticle species include conductive species suspended in fluid. In at least one example, the conductive species includes metals or alloys. In at least one example, conductive species can include one of: gold, silver, copper, or platinum nanoparticles. In at least one example, deposition of a single type of nanoparticle species in a single mask opening 306 has been described. In at least one example, the deposition process can be repeated over remaining openings 308, 310, and 312. For deposition to be continued within openings 308, 310, and 312, it is useful for openings 308, 310, and 312 to have structural integrity after deposition has been performed in opening 306. In at least one example, the same nanoparticle species can be deposited in openings 308, 310, and 312. In at least one example, different species of nanoparticles can be deposited within every alternate opening, for example gold can be deposited in opening 306 and opening 310, and silver can be deposited within opening 308 and 312. In at least one example, distinct nanoparticle species can be deposited within opening 306, opening 308, opening 310, and opening 312.

After nanoparticles 418 are deposited on layer 206, ink flow is turned off. In at least one example, ink flow is turned off by turning off ink source 410 and stop generating mist 416. In at least one example, plasma 414 is not turned off and ions exiting plasma can impart ion energy and to deposited conductive material 402. Plasma is capable of sintering nanoparticles within conductive material 402. In at least one example, print head assembly 404 can be moved in vertical direction and in horizontal direction (Y-axis direction). In at least one example, multiple passes of plasma 414 can assist in densifying conductive material 402. In at least one example, densification can increase and/or improve conductivity of conductive material 402. The height (or working distance) and speed of the treatment can be varied during both deposition and plasma treatment, and can be tuned for each material. In at least one example, a post-treatment process can be performed by varying height H₁ at a speed of approximately 1 mm/s to prevent heating of the substrate or the photoresist.

FIG. 4B illustrates a cross-section of deposition configuration 400B. In at least one example, deposition configuration 400B illustrates wafer 401 in FIG. 4A following a process to deposit a conductive material 422 within opening 308 on surface of layer 206 to form wafer 440. In at least one example, print head assembly 404 is moved across mask 302 to a location of opening 308. The process to deposit nanoparticles, described above (FIG. 4A) may be repeated. In at least one example, the same nanoparticle species as that of conductive material 402 can be deposited in opening 308. In at least one example, different nanoparticle species from that of conductive material 402 can be deposited within every alternate opening, for example gold can be deposited in opening 306 and opening 310, and silver be deposited within opening 308 and 312. In at least one example, distinct nanoparticle species can be deposited within opening 306, opening 308, opening 310, and opening 312. In at least one example, a mist 424 is introduced into plasma 426, where plasma 426 can comprise different gases from plasma 414 in FIG. 4A. In at least one example, nanoparticles 428 emanating from plasma 426 diffuse or are transported towards surface 302A and exposed surfaces of layer 206 within opening 306. In at least one example, characteristics of conductive material 422 within opening 308 includes one or more features of conductive material 402 deposited within opening 306 (such as flat profile, centered high profile, etc.). In at least one example, conductive material 422 is also deposited on portion of surface 302A. Depending on plasma and characteristics of nanoparticles 428 the deposition process may also coat portion of inner sidewalls of mask 302 within opening 310. In at least one example, print head assembly 404 is at a height H₂ above mask 302. In at least one example, height H₂ may be the same as height H₁ (FIG. 4A). In at least one example, height H₂ can be between 2 nm and 10 mm. For a given height diffusion or dispersion of nanoparticles from opening 412 can be dependent on material of nanoparticles. In at least one example, type of plasma implemented to deposit conductive material 422 can be different from the plasma implemented to deposit conductive material 402 (FIG. 4A). In at least one example, type of plasma implemented can depend on the gas utilized for example, helium, argon, nitrogen, or a mixture of two or more of hydrogen, helium argon, or nitrogen. In at least one example, height H₂ can vary with material deposited, which in turn depends on the ink utilized. In at least one example, to reduce dispersion or overspray, height H₂ can be between 2 mm to 5 mm (inclusive). In at least one example, conductive material 422 is deposited to a thickness that is the same or substantially the same as thickness of conductive material 402. In at least one example, conductive material 422 can be deposited to a different thickness (such as a lesser thickness) than conductive material 402 especially if the nanoparticle species in conductive material 422 can cause damage to resist. In at least one example, post deposition treatment described above may be carried out after depositing conductive material 422 and, more generally, may be carried out after each deposition process.

FIG. 4C illustrates a cross-section of deposition configuration 400C. In at least one example, deposition configuration 400C illustrates wafer 440 in FIG. 4B following a series of deposition processes to form wafer 450. In at least one example, the series of deposition processes include depositing a conductive material 430 on surface of layer 206 within opening 310, and a process to deposit conductive material 432 on surface of layer 206 within opening 312. In at least one example, conductive material 430 is deposited using print head assembly 404 by a process that is like one of the processes described in FIG. 4A or 4B. In at least one example, conductive material 430 may be deposited to a thickness that is same or different from thicknesses of conductive material 402 and/or conductive material 422. In at least one example, conductive material 430 includes metals or alloys. In at least one example, conductive material 430 includes one of: gold, silver, copper, or platinum nanoparticles. In at least one example, the deposition process can be continued to deposit conductive material 432. In at least one example, the deposition method is same or substantially same as that used to deposit conductive material 402, conductive material 422, or conductive material 430. In at least one example, mist 434 exiting from ink source 410 enters plasma 436. In at least one example, nanoparticles 438 leaving plasma 436 are deposited on to surface 302A of mask 302 and on surface of layer 206. In at least one example, depending on characteristics of plasma 436 and nanoparticles 438, the deposition process may also coat a portion of inner sidewalls of mask 302 within opening 312. In at least one example, while deposition within four openings is illustrated in FIGS. 4A-4C and described herein, the deposition method can be utilized to deposit conductive material in a large number of openings. Furthermore, the deposition method may be sequential, as discussed above, or can be carried out simultaneously using a plurality of print head assemblies as will be discussed below. In at least one example, spacing L_{O} between two adjacent mask openings and width of print head are factors that can determine rate of deposition within multiple openings. In at least one example, spacing L_{O} can be between 1 and 10 microns. In at least one example, spacing L_{O} can be up to 5 times a feature size, where feature size is width W₁.

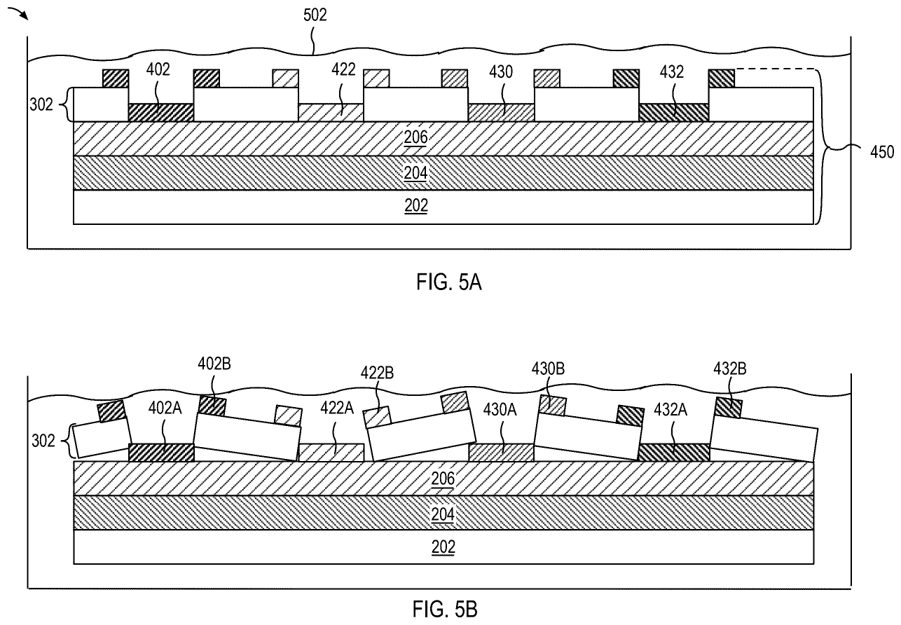

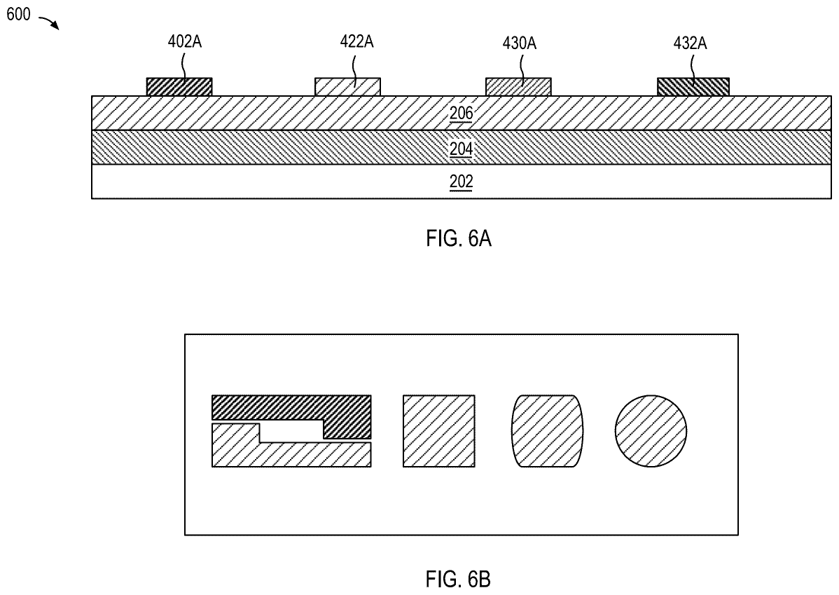

In at least one example, after the deposition process within all desired openings in wafer 300 (FIG. 3A) is complete, wafer 450 undergoes resist removal to define patterns formed within each opening. FIGS. 5A-6B illustrate the resist removal process.

FIG. 5A illustrates a cross-section of wafer 450 in FIG. 4C following a process to submerge wafer 450 into an aqueous solution 502, in at least one example. In at least one example, aqueous solution 502 includes a chemical that reacts with the photoresist in mask 302. In at least one example, the aqueous solution 502 includes acetone or an NMP based solvent stripper designed for efficient and complete removal of PMGI, PMMA, SU-8, and other resist films. Aqueous solution 502 includes a material that does not react with conductive material 402, conductive material 422, conductive material 430, conductive material 432, layer 206, layer 204, or substrate 202.

FIG. 5B illustrates a cross-section of structure in FIG. 5A following process to sonicate and remove mask 302 to form conductive patterns, in at least one example. In at least one example, the process of submerging wafer 450 may not remove mask 302 because the deposition process may chemically alter portions of the mask. The profile of the openings within mask 302 can provide for conductive material deposition along the base and at a bottom portion of the photoresist making up mask 302. In at least one example, ultrasonic agitation may be performed to expedite removal or mask 302. The objective of the agitation process is to remove portions of conductive materials that are on the resist and leave conductive materials on the surface of layer 206. In at least one example, ultrasonic agitation may be performed for a short duration to prevent delamination of conductive film from surface of layer 206. In at least one example, ultrasonic agitation may be performed for a duration of 30 seconds to 2 minutes to prevent delamination. In at least one example, conductive material portion 402A, conductive material portion 422A, conductive material portion 430A, and conductive material portion 432A remain on surface of layer 206, whereas conductive material portion 402B, conductive material portion 422B, conductive material portion 430B, and conductive material portion 432B that are deposited on photoresist material of mask 302 are removed, as illustrated.

FIG. 6A illustrates a cross-section of wafer 600. In at least one example, wafer 600 is an illustration of wafer 450 in FIG. 5B following process to form conductive patterns. In at least one example, the conductive patterns illustrated include conductive material portion 402A, conductive material portion 422A, conductive material portion 430A, and conductive material portion 432A. In at least one example, after ultrasonic agitation is complete, wafer 600 is rinsed by IPA and deionized water and dried to remove surface contaminants.

FIG. 6B is a plan view illustration of a portion of wafer 600 in FIG. 6A, in at least one example. In at least one example, the patterns can be squares, circles, lines, rectangles, other geometric shapes or any arbitrary shape.

In some examples, it may be important to deposit multiple conductive materials within a single opening by stacking them. The method described above may be modified to accomplish stacking multiple conductive materials in a single process introduction into a deposition toolset as described below. A single process introduction can be useful to reduce the introduction of contaminants on surface of wafer during process flow.

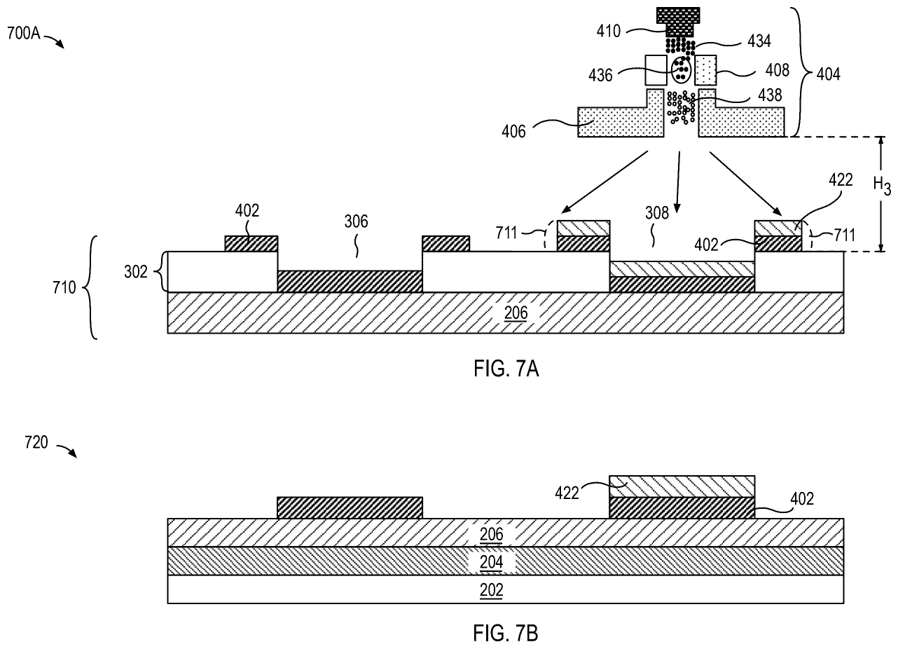

FIG. 7A illustrates a cross-section of deposition configuration 700A. In at least one example, deposition configuration 700A illustrates wafer 401 in FIG. 4A, following a series of process depositions to form wafer 710. In at least one example, the series of deposition processes include depositing conductive material 402 in opening 308, followed by a process to deposit conductive material 422 on conductive material 402 in opening 308. In at least one example, process and materials utilized to deposit conductive material 402 in opening 306 is repeated to deposit conductive material 402 into opening 308. In at least one example, method to deposit conductive material 422 (described in FIG. 4B) is repeated to deposit conductive material 422 within opening 308. In at least one example, the process to deposit conductive material 422 may include some variations to the process discussed above (FIG. 4B) because conductive material 422 is deposited on another conductive material in contrast to deposition on layer 206. In at least one example, height H₃ of print head assembly 404 may also be changed to account for thickness of conductive material 402. In at least one example, height H₃ may be greater than height H₂. In at least one example, portion of 422 deposited on mask 302 may completely cover conductive material 402 as indicated by dashed lines 711. In at least one example, a combined thickness of conductive material 402 and conductive material 422 is substantially less than a thickness of mask 302 and may facilitate removal of mask 302.

FIG. 7B illustrates a cross-section of wafer 720. In at least one example, wafer 720 illustrates wafer 710 in FIG. 7A, following process to remove mask 302 and form a first pattern comprising a conductive material 402 in one location and a second pattern comprising dual conductive layers in a second location on layer 206. In at least one example, the dual conductive layers comprise a stack of conductive material 402 and conductive material 422 on conductive material 402.

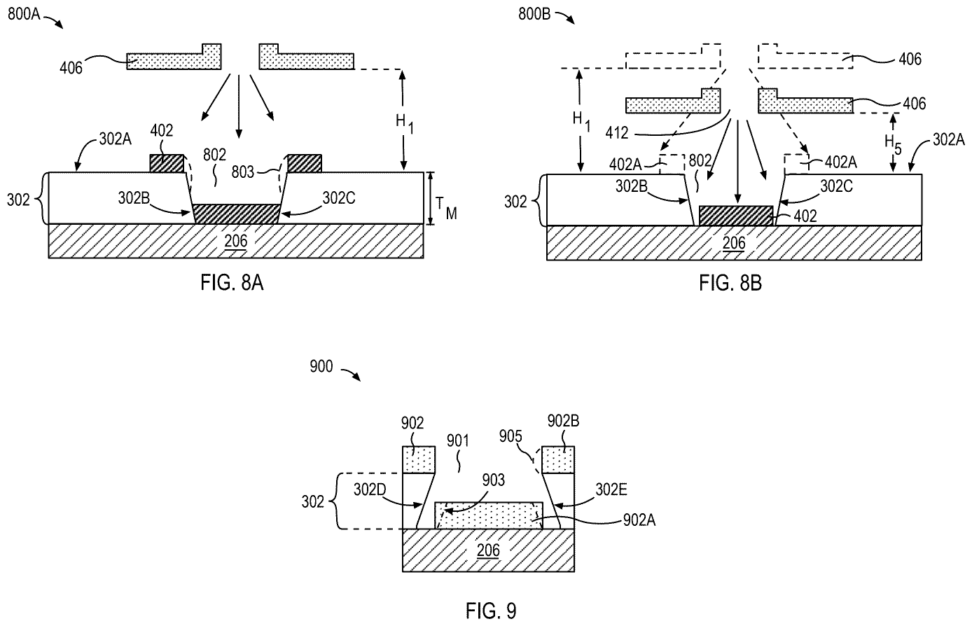

FIG. 8A illustrates a cross-section of deposition configuration 800A illustrating impact of flared resist on nanoparticle deposition, in at least one example. In at least one example, mask 302 includes an opening 802 that is flared as indicated by taper in sidewalls 302B and 302C. In at least one example, the deposition process described above (FIG. 4A) can cause nanoparticles to be deposited on at least a portion of sidewalls 302B and 302C as indicated by dashed line 803. In at least one example, depending on the thickness T_{M} of mask 302 and thickness of conductive material 402 deposited, nanoparticles may be deposited on entire sidewall 302B and 302C, making it difficult for mask removal. In at least one example, pillars of conductive material can protrude upwards after mask removal, where the pillars can delaminate during further processing. In at least one example, plasma jet printing technique, when used in conjunction with photoresist mask, may offer flexibility to adjust height of print head 406 from surface 302A. In at least one example, height H₁ may be adjusted to reduce a deposition solid angle.

FIG. 8B illustrates a cross-section of deposition configuration 800B, illustrating the effect of reducing height of print head from above mask 302 on nanoparticle deposition, in accordance with at least one example. In at least one example, reducing height of print head from above surface 302A to a height H₅ from H₁ (where H₅ is less than H₁), can reduce a solid angle for deposition. In at least one example, height H₅ can be up to 10 mm. In at least one example, depending on the size of opening 412 of print head 406 compared to size of opening 802 in mask 302, diffusion of nanoparticles may be confined to a space within sidewalls of opening 802, as illustrated.

In at least one example, where size of opening 412 of print head 406 is equal to or larger than the size of opening 802, diffusion of nanoparticles may cause deposition on sidewalls 302B and 302C. In at least one example, reducing the deposition height to height H₅ from height H₁ may be useful to confine nanoparticles to lower portions of sidewalls 302B and 302C. Reducing deposition along entire sidewall 302B and 302C not only facilitates mask removal but can minimize residual conductive material attached to portions of conductive material 402. In at least one example, residual conductive material may not have structural integrity and present problems as discussed above.

FIG. 9 illustrates a cross-section of a structure 900. In at least one example, structure 900 is an illustration of structure 330 in FIG. 3D, following process of deposition through an opening 901 that comprises a re-entrant profile. In at least one example, a reentrant profile may be useful depending on the relationship between the thickness of photoresist in mask 302, size of opening 901, thickness of conductive material 902 deposited, and height of print head (not shown) above mask 302. In at least one example, the position of print head above mask 302 and size of opening in print head can force deposition of conductive material 902 on surface 302A of mask 302. In at least one example, deposition of conductive material 902 can extend laterally for at least 100 nm. In at least one example, a reentrant sidewall profile of opening 901 of mask 302 can be useful to prevent deposition along sidewalls 302D and 302E, where sidewalls 302D and 302E may be hidden by line of sight of impinging nanoparticles. In at least one example, portion 902A of conductive material 902 deposited on layer 206 can have a vertical or substantially vertical profile. In at least one example, portion 902A can have a tapered profile indicated by dashed lines 903. In at least one example, a tapered profile can form as portion 902B laterally expands with continued deposition as indicated by dashed lines 905. In at least one example, a line of sight of deposition for nanoparticles enhances lateral growth of portion 902B with increase in deposition time, and size of opening 901 decreases with deposition time. In at least one example, advantages of re-entrant profile can be enhanced when thickness of photoresist of mask is 100 nm or less and material deposited is 50% of a thickness of mask 302.

Referring again to FIG. 4A, the distance between surface 302A of mask 302 and print head 406 may depend on nanoparticle and characteristics of plasma discharge implemented, such as species and plasma potential. In some examples, it may be useful to maintain a minimum distance between surface 302A of mask 302 and print head 406 for operational reasons. In at least one example, when openings within mask 302 are substantially vertical or slanted, it may be useful to limit the amount of deposition of conductive material on surface 302A. A modification to the deposition configuration illustrated in FIG. 4A may be useful to limit the amount of deposition of conductive material on surface 302A, as will be discussed below.

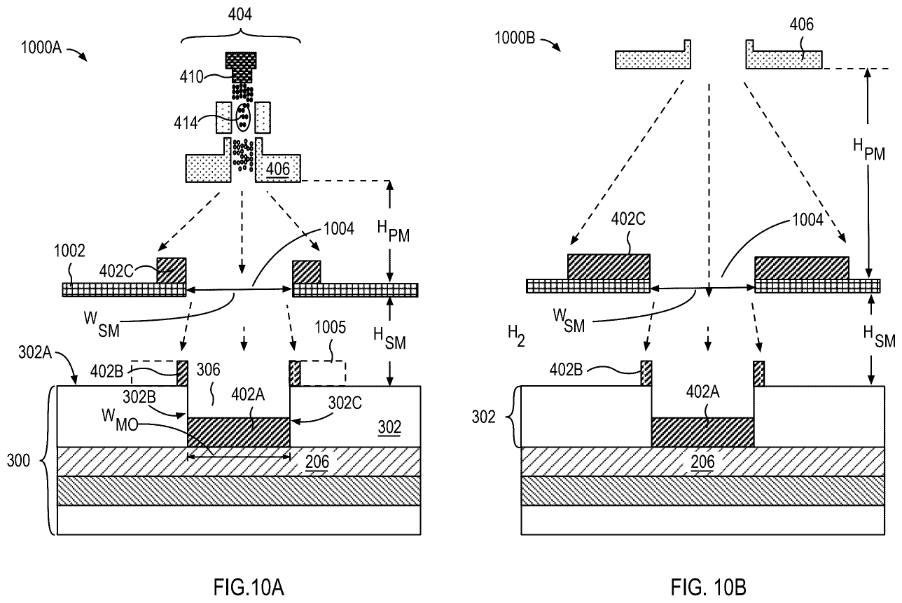

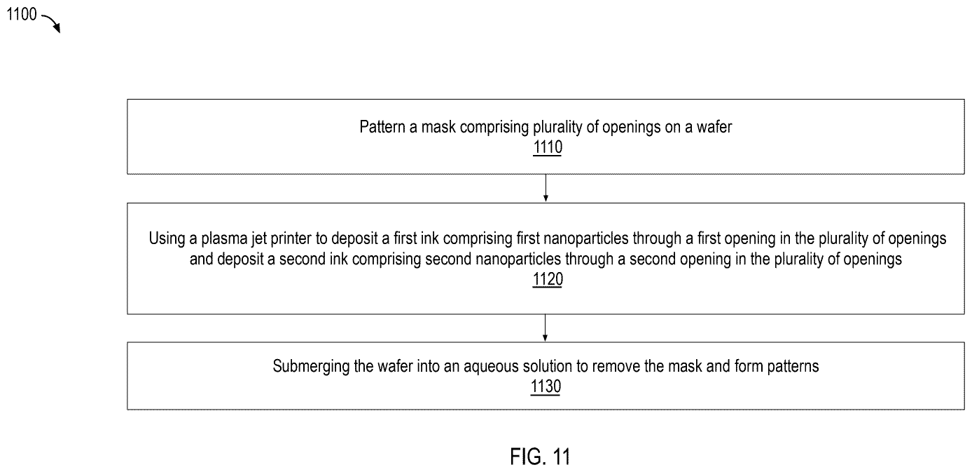

FIG. 10A illustrates a cross section of a deposition configuration 1000A. In at least one example, deposition configuration 1000A is a variation of deposition configuration 400A in FIG. 4A. In at least one example, deposition configuration 1000A illustrates deposition of conductive material 402 through dual masks. In at least one example, a first mask of the dual masks is mask 302, and a second mask of the dual masks may be implemented between print head 406 and surface 302A. In at least one example, the second mask may be a shadow mask 1002 that may be implemented vertically between print head 406 and mask 302. In at least one example, shadow mask 1002 is at a height H_{SM} above mask 302. In at least one example, height H_{SM} is at least 10 microns to prevent contact with surface 302A. In at least one example, print head 406 is at a height H_{PM} above shadow mask 1002. In at least one example, height H_{PM} is at least 25 microns to prevent physical contact and electromagnetic interaction between print head 406 and shadow mask 1002. In at least one example, the shadow mask comprises an insulative material or a conductive material such as Silicon, polyamide, metal, or glass. In at least one example, shadow mask 1002 can comprise a thickness of at least 10 microns. In at least one example, shadow mask 1002 may be mechanically coupled with print head assembly 404, and height H_{PM} may be adjustable with reference to base of print head 406. In at least one example, shadow mask 1002 is part of a stage that houses wafer 300, where height H_{SM} is adjustable with reference to surface of a stage (and surface 302A).

In at least one example, opening 1004 in shadow mask 1002 presents a line of sight for deposition of nanoparticles on surface of layer 206. Opening 1004 comprises a width W_{SM}. In at least one example, opening 1004 is designed to reduce a large lateral spread (along x and y axis directions) in nanoparticle deposition on surface 302A. In at least one example, width W_{SM} is comparable to width W_{MO} of opening 306. In at least one example, utilization of shadow mask 1002 blocks a conductive material portion 402C of conductive material 402 from entering opening 1004, and conductive material portion 402C is deposited on upper surface of shadow mask 1002. In at least one example, portion 402A is deposited in opening 306. In at least one example, conductive material portion 402B may be deposited on surface 302A due to diffusion of nanoparticles despite presence of shadow mask 1002. The lateral spread of conductive material portion 402B will depend on height H_{SM}, width W_{MO}, and width W_{SM}. In at least one example, height H_{SM} can be up to 100 microns, width W_{MO} can be up to several hundred microns, and width W_{SM} can be up to several hundred microns. In at least one example, width W_{MO} can be sub-micron such as between 100 nm to 250 nm. In at least one example, sub-micron feature sizes can be patterned by electron beam lithography. In at least one example, a lateral spread in conductive material portion 402B, on surface 302A, in absence of shadow mask is outlined by dashed lines 1005. In at least one example, deposition on sidewalls 302B and 302C may be mitigated because of shadow mask 1002. Mitigating deposition on sidewalls 302B and 302C that may be flared can be useful for integrity of final patterned structure, as discussed above. In at least one example, width W_{SM} is less than width W_{MO}. In at least one example, conductive material portion 402B may not be formed on surface 302A. In at least one example, conductive material portion 402A may not extend a full width W_{MO} on surface of layer 206.

In some examples, a minimum height H_{PM} may be greater than 1 mm. In at least one example, changes in height H_{PM} may be determined by plasma configurations within print head assembly and on choice of nanoparticles deposited. In at least one example, utilization of shadow mask 1002 in conjunction with mask 302 may be useful to prevent substantial deposition of conductive material 402 on surface 302A, as illustrated in deposition configuration 1000B in FIG. 10B. In at least one example, when height H_{PM} is increased in deposition configuration 1000B compared to height H_{PM} illustrated in FIG. 10A (such as 10 times greater), characteristics of nanoparticle deposition within opening 306 and on mask 302 and may not be substantially different because of presence of shadow mask 1002. In at least one example, at edge regions of opening 1004 there can be additional diffusion due to a longer path from an increased height H_{PM}. In at least one example, lateral extent of conductive material portion 402B in FIG. 10B can be greater than in FIG. 10A, but not by the same factor as the change in height H_{PM} between deposition configuration 1000A and deposition configuration 1000B.

Referring again to FIGS. 4A-4C, in at least one example, conductive material 402, conductive material 422, conductive material 430, and conductive material 432 may be deposited simultaneously into openings 306, 308, 310, and 312, respectively, using a plasma jet printer comprising a multi print head configuration.

FIG. 11 is a flow diagram for method 1100 to form nanoscale conductive patterns using multiple print heads, in at least one example. In at least one example, method 1100 begins at operation 1110 with patterning a mask comprising plurality of openings on a wafer. In at least one example, method 1100 continues at operation 1120 by using a plasma jet printer to deposit a first ink comprising first nanoparticles through a first opening in the plurality of openings and a second ink comprising second nanoparticles through a second opening in the plurality of openings. In at least one example, method 1100 concludes at operation 1130 by submerging the wafer into an aqueous solution to remove the mask and form patterns. Depending on embodiments, the first ink and second ink can be same or different and the first opening and second opening can be the same shape and size or different. Other parameters such as materials of ink and methods of removal of mask will be discussed below. In at least one example, a system that can simultaneously deposit two or more nanoparticles in a respective mask opening, can offer efficiency in operation without sacrificing quality of final product.

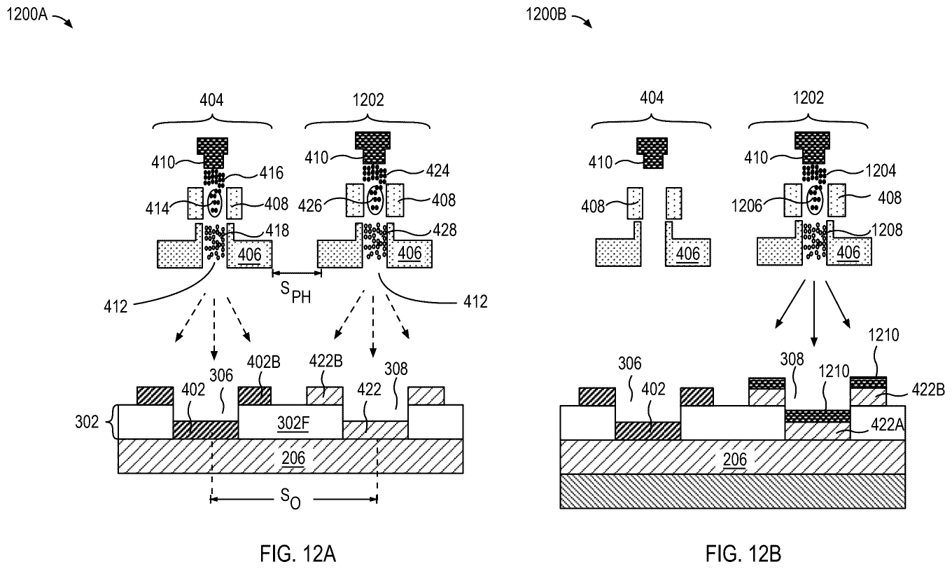

FIG. 12A illustrates a cross-section of a deposition configuration 1200A. In at least one example, deposition configuration 1200A illustrates a portion of structure 320 in FIG. 3C following a process to use multiple print heads to simultaneously deposit nanoparticles within different openings. In at least one example, deposition configuration 1200A illustrates two print head assemblies, such as print head assembly 404 and print head assembly 1202. In at least one example, print head assembly 1202 includes all the components of print head assembly 404 such as ink source 410, electrodes 408, and print head 406. In at least one example, print head assembly 1202 is laterally spaced apart from print head assembly 404 by a spacing S_{PH}. In at least one example, spacing S_{PH} is a function of tool parameter and may be adjustable. In at least one example, spacing S_{PH} may be adjusted so that an axial center of opening 412 of respective print head assembly is substantially above an approximate center of opening 306 and opening 308 (when openings are regularly shaped).

In at least one example, print head assembly 404 is utilized to deposit conductive material 402 within opening 306, and print head assembly 1202 is utilized to deposit conductive material 422 within opening 308. In at least one example, methods of sequential deposition of conductive material 402 and conductive material 422 have been described above. In at least one example, the method of simultaneous deposition, as described herein, is the same or substantially the same. In at least one example, print head assembly 404 and print head assembly 1202 are turned on at the same time. In at least one example, the time duration for depositing conductive material 402 may be different from time duration for deposition of conductive material 422. In at least one example, portion 302F of mask 302 has a lateral thickness that prevents overlap between conductive material portion 402B and conductive material portion 422B during the deposition process. In at least one example, deposition times for depositing conductive material 402 may be different from depositing conductive material 422.

FIG. 12B illustrates a cross-section of a deposition configuration 1200B where nanoparticles are deposited within a single opening in mask 302, in at least one example. In at least one example, after deposition of conductive material 422, a mist 1204 comprising nanoparticles (different from mist 424) may be injected using print head assembly 1202. In at least one example, a plasma 1206 may be applied and nanoparticles 1208 exiting print head 406, may be deposited. In at least one example, conductive material 1210 is formed on surface of conductive material portion 422A within opening 308 and on conductive material portion 422B above mask 302. In at least one example, a dual conductive material stack, including conductive material 1210 on conductive material 422, may be implemented in circuitry requiring conductive materials with different work functions.

In at least one example, print head assembly 404 may be turned off while print head assembly 1202 is operational. In at least one example, deposition of conductive material 422 and conductive material 1210 may be performed while deposition of conductive material 402 is performed within opening 306. In both examples described, overlap between conductive material 402 and conductive material 422 or conductive material 1210 should be minimized to contaminate devices. In other examples, size of opening 306 and opening 308 may require print head 406 to be at a height that can cause overlap between nanoparticles simultaneously deposited into multiple openings.

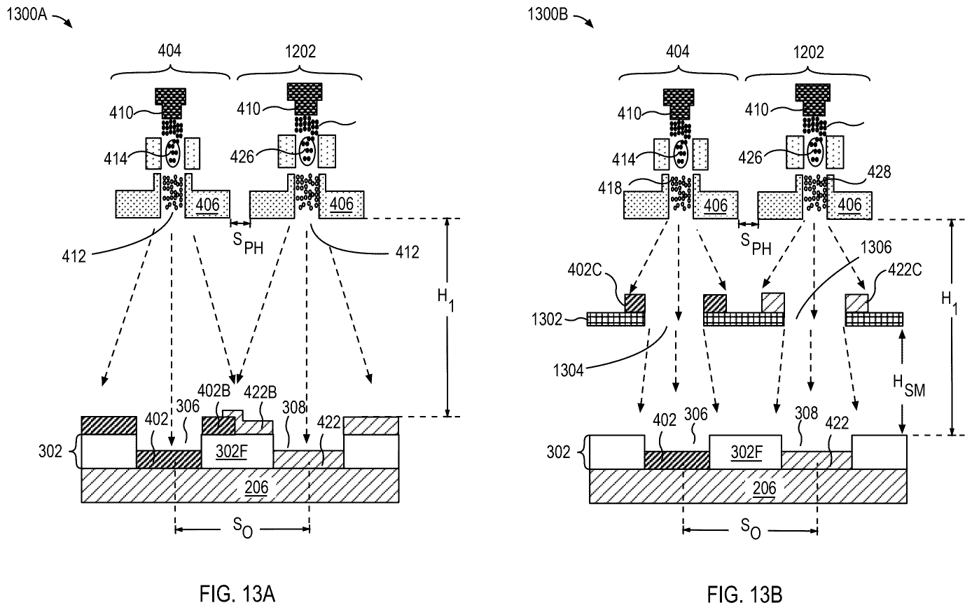

FIG. 13A illustrates a cross-section of a deposition configuration 1300A where multiple print heads are utilized to simultaneously deposit nanoparticles within different openings in mask 302, in at least one example. In at least one example, simultaneous deposition process can cause overlap in deposition of different nanoparticles. In at least one example, pitch S_{O} may be reduced compared to pitch S_{O} in mask 302 in FIG. 12A causing a reduction in ratio of pitch S_{O}: spacing S_{PH}. In at least one example, a fixed height H₁ can cause nanoparticles from print head assembly 404 and print head assembly 1202 to interfere at surface 302A during deposition. Interference may be defined as an overlap between conductive material portion 402B and conductive material portion 422B, and as shown in the figure. In at least one example, height H₁ may be a minimum height that print head assembly 404 and print head assembly 1202 can be above surface 302A. In at least one example, increasing H₁ can cause nanoparticles from print head assembly 404 to be deposited into an adjacent opening (such as opening 308). In at least one example, when opening 306 and opening 308 have slanted or tapered sidewalls, mixed deposition can also take place on slanted or tapered sidewalls presenting difficulty during mask removal.

FIG. 13B illustrates a cross-section of a deposition configuration 1300B, where implementing a shadow mask 1302 can prevent overlap of different nanoparticles during simultaneous deposition, in at least one example. In at least one example, shadow mask 1302 comprises properties of shadow mask 1002 (FIG. 10A). In at least one example, shadow mask 1302 includes a plurality of openings, such as opening 1304 and opening 1306 for nanoparticles to pass through from one or two different print heads. In at least one example, size of opening 1304 and opening 1306 may be chosen based on placement or height H_{SM} of shadow mask 1302 relative to a top surface of mask 302. In at least one example, opening 1304 and opening 1306 can be 250nm to several hundred microns. In at least one example, height H_{SM} can be up to 10 mm. In at least one example, height H_{SM} of up to 10 mm can provide interaction of plasma with the material deposited for self-sintering. In at least one example, other than implementing shadow mask 1302, deposition configuration 1300B is the same or substantially the same as deposition configuration 1300A. In at least one example, by implementing shadow mask 1302 a first portion of nanoparticles 418 and a second portion of nanoparticles 428 may deposit on surface of shadow mask 1302, and remaining portions of respective nanoparticles may pass through opening 1304 and opening 1306 towards opening 306 and opening 308. In at least one example, depending on ratio between height H_{1:} height H_{SM}, diffusion angles of nanoparticles passing though opening 1304 can be controlled. Herein, diffusion angle is measured relative to a normal to surface of shadow mask 1302. In at least one example, controlling diffusion angles may be useful to control deposition characteristics of conductive material 402 and conductive material 422 on surface of layer 206 and in the vicinity of mask 302. In at least one example, conductive material portion 402C and conductive material portion 422C deposited on shadow mask 1302 may merge without adverse effect on deposition on layer 206 below.

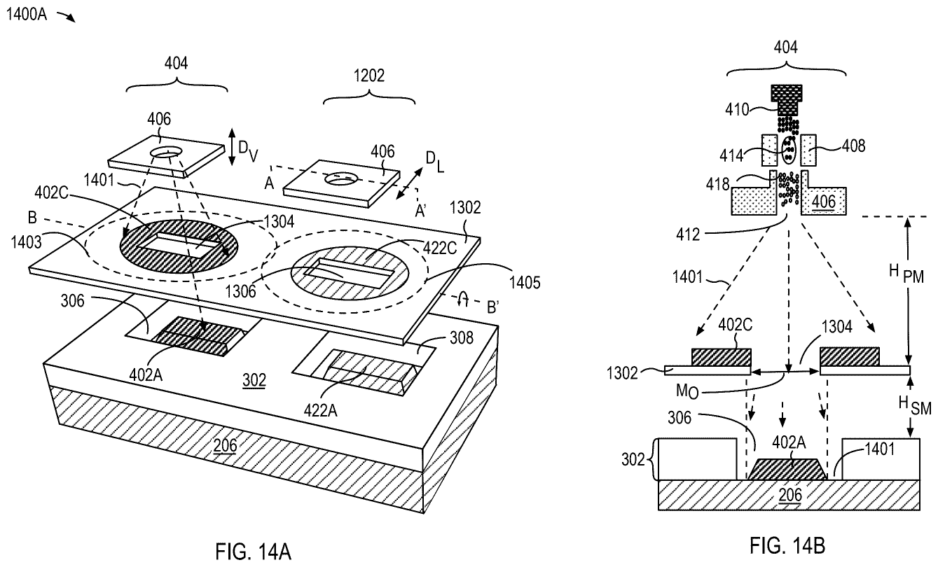

FIG. 14A is an isometric illustration of a deposition configuration 1400A, where implementing a shadow mask 1302 can prevent overlap between nanoparticles emanating from two different sources during simultaneous deposition, in at least one example. In at least one example, opening 1304 and opening 1306 can have an arbitrary shape that matches a shape of opening 306 and opening 308, respectively. In at least one example, opening 306 and opening 308 can have a geometrically defined shape such as a circle, an ellipse, or a rectangle. In at least one example, nanoparticles exiting plasma generated within print head assembly 404 pass through opening in print head 406 and are distributed into a conical pattern as indicated by arrows 1401. A portion of nanoparticles generated within print head assembly 404 are deposited on surface of shadow mask 1302 and form conductive material portion 402C and a remaining portion may pass through opening 1304 towards opening 306. In at least one example, opening 1304 has a smaller size compared to opening 306. In at least one example, deposition may be confined to a portion of surface of layer 206 that is within boundaries of photoresist that define opening 306.

In at least one example, nanoparticles exiting plasma generated within print head assembly 1202 pass through opening in print head 406 and are distributed in a conical pattern. In at least one example, the portion of nanoparticles generated within print head assembly 1202 are deposited on surface of shadow mask 1302 and form conductive material portion 422C and a remaining portion may pass through opening 1306 towards opening 308. In at least one example, opening 1306 has a smaller size compared to opening 308. In at least one example, deposition may be confined to a portion of surface of layer 206 that is within boundaries of photoresist defining opening 308.

As discussed above, deposition of conductive material portion 402A and conductive material portion 422A may happen simultaneously, or sequentially and deposition times can vary depending on materials deposited and thicknesses chosen. In at least one example, print head assembly 404 and print head assembly 1202 can be displaced about an equilibrium position by an amount +/−D_{V} along a vertical direction (Z-axis direction) and laterally by an amount +/−D_{L} (Y-axis direction). Increasing D_{V} (away from surface of shadow mask 1302 can increase a solid angle subtended at shadow mask 1302 and cause greater surface coverage on shadow mask 1302, as indicated by dashed circles 1403 and 1405. In at least one example, deposition can overlap on shadow mask 1302 but not affect deposition on mask 302 below. In at least one example, the shape and size of shadow mask 1302 can be altered to reduce unwanted deposition on mask 302. In at least one example, shadow mask 1302 can be rotated about an axis defined by line B-B′. Rotation about line B′B′ can control deposition area within opening 306 and opening 308.

FIG. 14B is a cross-sectional illustration of a portion of the deposition configuration 1400A in FIG. 14A. In at least one example, nanoparticles 418 exiting plasma 414 generated between electrodes 408 pass through opening 412 in print head 406 and are distributed in a conical pattern (indicated by arrows 1401). A portion of nanoparticles 418 are deposited on surface of shadow mask 1302 and form conductive material portion 402C and a remaining portion may pass through opening 1306 towards opening 306. In at least one example, opening 1306 has a smaller width compared to opening 308. In at least one example, deposition may be confined to a portion of surface of layer 206 that is within boundaries of photoresist defining opening 308. In at least one example, the deposition conditions form conductive material portion 402A with slanted sidewalls, as shown.

Referring again to FIG. 14A, in at least one example, lateral spacing between openings 306 and 308 is much less than a lateral spacing between housings of print head assembly 404 and print head assembly 1202, respectively. In at least one example, a single print head assembly 404 can be moved relative to shadow mask 1302 to perform sequential deposition in openings 306 and 308. In at least one example, height H_{PM} (FIG. 14B) of print head assembly 404 can control a lateral spread in nanoparticles deposited. In at least one example, height H_{PM} can be up to 10 mm.

Example 1 is a method of forming a patterned conductive film, the method comprising: preparing a wafer for deposition, the method comprising: forming at least a layer above a substrate; and patterning a mask comprising a photoresist material on the layer, wherein the mask comprises a plurality of openings; using a plasma jet printer to direct a print head assembly towards an opening within the plurality of openings, wherein the print head assembly comprises an ink dispenser comprising a nanoparticle module; depositing nanoparticles, wherein a first portion of the nanoparticles is formed on the layer, and a second portion of the nanoparticles is formed on an uppermost surface of the mask; and performing submersion of the wafer into an aqueous solution and dissolving portions of the photoresist material in contact with the layer to dislocate the second portion of the nanoparticles and leave the first portion of the nanoparticles to form the patterned conductive film.

Example 2 is a method according to any method described herein, in particular example 1, wherein performing submersion of the wafer further comprises agitating the aqueous solution by performing sonication for a time duration of at least 30 seconds.

Example 3 is a method according to any method described herein, in particular example 1, wherein individual ones of the plurality of openings comprise a minimum width of 100 nm to 500 microns.

Example 4 is a method according to any method described herein, in particular example 1, wherein the nanoparticles comprise a metal including one of: gold, platinum, silver, copper, etc.

Example 5 is a method according to any method described herein, in particular example 1, wherein the nanoparticles comprise an alloy including one of: gold, platinum, silver, copper, etc.

Example 6 is a method according to any method described herein, in particular example 1, wherein prior to performing submersion of the wafer the method further comprises: directing the print head assembly towards a second opening within the plurality of openings; and depositing second nanoparticles, wherein a third portion of the second nanoparticles is formed on the layer, and a fourth portion of the second nanoparticles is formed on the uppermost surface of the mask and wherein performing submersion of the wafer further comprises dissolving second portions of the photoresist material in contact with the layer to dislocate the fourth portion of the second nanoparticles and leave the third portion of the nanoparticles to form a second patterned conductive film.

Example 7 is a method according to any method described herein, in particular example 5, wherein after depositing the nanoparticles the wafer is not heated prior to performing submersion of the wafer.

Example 8 is a method according to any method described herein, in particular example 1, wherein prior to using the plasma jet printer the method further comprises: inserting a shadow mask between the mask and the print head assembly, wherein the mask comprises a second opening aligned with the opening in the plurality of openings in the mask, and wherein the shadow mask comprises a conductive or insulator material.

Example 9 is a method of forming a patterned conductive film, the method comprising: preparing a wafer for deposition, the method comprising: forming a layer above a substrate; and patterning a mask comprising a photoresist material on the layer, wherein the mask comprises a first opening and a second opening; performing the deposition using a plasma jet printer, the plasma jet printer comprising a first module and a second module, wherein the first module is utilized to direct a first ink comprising first nanoparticles towards the first opening and deposit the first nanoparticles on a first portion of the layer, and wherein the second module is utilized to direct a second ink comprising second nanoparticles towards the second opening and deposit the second nanoparticles on a second portion of the layer; and performing submersion of the wafer into an aqueous solution and dissolving first portions of the photoresist material in contact with the layer to dislocate second portions of the first nanoparticles and third portions of the second nanoparticles formed on the mask.

Example 10 is a method according to any method described herein, in particular example 9, wherein the first module and the second module are simultaneously operated.

Example 11 is a method according to any method described herein, in particular example 9, wherein depositing the first nanoparticles and dissolving the first portions of the photoresist material comprises forming a first conductive pattern, and wherein depositing the second nanoparticles and dissolving the first portions of the photoresist material comprises forming a second conductive pattern.

Example 12 is a method according to any method described herein, in particular example 9, wherein the first nanoparticles comprise one of gold, silver, copper, or platinum nanoparticles and the second nanoparticles comprise one of gold, silver, copper, or platinum nanoparticles.

Example 13 is a method according to any method described herein, in particular example 9, wherein the mask further comprises a third opening and a fourth opening, wherein prior to performing submersion, the first module is moved above the third opening and the second module is moved above the fourth opening and re-performing the deposition.

Example 14 is a method according to any method described herein, in particular example 9, wherein depositing the first nanoparticles through the third opening forms a third conductive pattern, and wherein depositing the second nanoparticles through the fourth opening comprises forming a fourth conductive pattern.

Example 15 is a method according to any method described herein, in particular example 9, wherein the first opening and the second opening are separated by a distance of 1-10 microns or more.

Example 15 is a method of forming a patterned conductive film, the method comprising: preparing a wafer for deposition, the method comprising: forming at least a layer above a substrate; and patterning a mask comprising a photoresist material on the layer, wherein the mask comprises a first opening and a second opening positioning a plasma jet printer above the wafer; placing a shadow mask between the plasma jet printer and the wafer, wherein the shadow mask comprises a third opening and a fourth opening, wherein the first opening is vertically aligned with the third opening, and the second opening is vertically aligned with the fourth opening; performing the deposition using the plasma jet printer, the plasma jet printer comprising a first module and a second module, wherein the first module is utilized to direct a first ink comprising first nanoparticles towards the first opening and deposit the first nanoparticles on a first portion of the layer, and wherein the second module is utilized to direct a second ink comprising second nanoparticles towards the second opening and deposit the second nanoparticles on a second portion of the layer; and performing submersion of the wafer into an aqueous solution and dissolving portions of the photoresist material in contact with the layer to dislocate a third portion of the first nanoparticles and fourth portion of the second nanoparticles formed on the mask and leave fifth portion of first nanoparticles and sixth portion of the second nanoparticles on the layer.

Example 17 is a method according to any method described herein, in particular example 16, wherein the third opening is smaller than the first opening and wherein the second opening is smaller than the fourth opening.

Example 18 is a method according to any method described herein, in particular example 16, wherein the first nanoparticles enter through the third opening and wherein a seventh portion of the first nanoparticles is deposited on an upper surface of the shadow mask and wherein the second nanoparticles enter through the fourth opening and wherein an eighth portion of the second nanoparticles is deposited on the upper surface of the shadow mask.

Example 19 is a method according to any method described herein, in particular example 16, wherein the first opening and the second opening are separated by a lateral distance of at least 1-10 micros or more.

Example 20 is a method according to any method described herein, in particular example 18, wherein the first nanoparticles comprise one of [list materials] and the second nanoparticles comprise one of: gold, silver, copper, or platinum nanoparticles.

What is claimed is:

1. A method of forming a patterned conductive film, the method comprising:
preparing a wafer for deposition, the method comprising:
forming at least a layer above a substrate; and
patterning a mask comprising a photoresist material on the layer, wherein the mask comprises a plurality of openings;
using a plasma jet printer to direct a print head assembly towards an opening within the plurality of openings, wherein the print head assembly comprises an ink dispenser comprising a nanoparticle module;
depositing nanoparticles, wherein a first portion of the nanoparticles is formed on the layer, and a second portion of the nanoparticles is formed on an uppermost surface of the mask; and
performing submersion of the wafer into an aqueous solution and dissolving portions of the photoresist material in contact with the layer to dislocate the second portion of the nanoparticles and leave the first portion of the nanoparticles to form the patterned conductive film.

2. The method of claim 1, wherein performing submersion of the wafer further comprises agitating the aqueous solution by performing sonication for a time duration of at least 30 seconds.

3. The method of claim 1, wherein individual ones of the plurality of openings comprise a minimum width of 100 nm to 500 microns.

4. The method of claim 1, wherein the nanoparticles comprise a metal including one of: gold, silver, copper, or platinum nanoparticles.

5. The method of claim 1, wherein the nanoparticles comprise an alloy including two or more of: gold, silver, copper, or platinum nanoparticles.

6. The method of claim 1, wherein prior to performing submersion of the wafer the method further comprises:
directing the print head assembly towards a second opening within the plurality of openings; and
depositing second nanoparticles, wherein a third portion of the second nanoparticles is formed on the layer, and a fourth portion of the second nanoparticles is formed on the uppermost surface of the mask and wherein performing submersion of the wafer further comprises dissolving second portions of the photoresist material in contact with the layer to dislocate the fourth portion of the second nanoparticles and leave the third portion of the nanoparticles to form a second patterned conductive film.

7. The method of claim 5, wherein after depositing the nanoparticles the wafer is not heated prior to performing submersion of the wafer.

8. The method of claim 1, wherein prior to using the plasma jet printer the method further comprises:
inserting a shadow mask between the mask and the print head assembly, wherein the mask comprises a second opening aligned with the opening in the plurality of openings in the mask, and wherein the shadow mask comprises a conductive or insulator material.

9. A method of forming a patterned conductive film, the method comprising:
preparing a wafer for deposition, the method comprising:
forming a layer above a substrate; and
patterning a mask comprising a photoresist material on the layer, wherein the mask comprises a first opening and a second opening;
performing the deposition using a plasma jet printer, the plasma jet printer comprising a first module and a second module, wherein the first module is utilized to direct a first ink comprising first nanoparticles towards the first opening and deposit the first nanoparticles on a first portion of the layer, and wherein the second module is utilized to direct a second ink comprising second nanoparticles towards the second opening and deposit the second nanoparticles on a second portion of the layer; and
performing submersion of the wafer into an aqueous solution and dissolving first portions of the photoresist material in contact with the layer to dislocate second portions of the first nanoparticles and third portions of the second nanoparticles formed on the mask.

10. The method of claim 9, wherein the first module and the second module are simultaneously operated.

11. The method of claim 9, wherein depositing the first nanoparticles and dissolving the first portions of the photoresist material comprises forming a first conductive pattern, and wherein depositing the second nanoparticles and dissolving the first portions of the photoresist material comprises forming a second conductive pattern.

12. The method of claim 9, wherein the first nanoparticles comprise one of gold, silver, copper, or platinum nanoparticles and the second nanoparticles comprise one of gold, silver, copper, or platinum nanoparticles.

13. The method of claim 9, wherein the mask further comprises a third opening and a fourth opening, wherein prior to performing submersion, the first module is moved above the third opening and the second module is moved above the fourth opening and re-performing the deposition.

14. The method of claim 13, wherein depositing the first nanoparticles through the third opening forms a third conductive pattern, and wherein depositing the second nanoparticles through the fourth opening comprises forming a fourth conductive pattern.

15. The method of claim 9, wherein the first opening and the second opening are separated by a distance of 1-10 microns or more.

16. A method of forming a patterned conductive film, the method comprising:
preparing a wafer for deposition, the method comprising:
forming at least a layer above a substrate; and
patterning a mask comprising a photoresist material on the layer, wherein the mask comprises a first opening and a second opening;
positioning a plasma jet printer above the wafer;
placing a shadow mask between the plasma jet printer and the wafer, wherein the shadow mask comprises a third opening and a fourth opening, wherein the first opening is vertically aligned with the third opening, and the second opening is vertically aligned with the fourth opening;
performing the deposition using the plasma jet printer, the plasma jet printer comprising a first module and a second module, wherein the first module is utilized to direct a first ink comprising first nanoparticles towards the first opening and deposit the first nanoparticles on a first portion of the layer, and wherein the second module is utilized to direct a second ink comprising second nanoparticles towards the second opening and deposit the second nanoparticles on a second portion of the layer; and
performing submersion of the wafer into an aqueous solution and dissolving portions of the photoresist material in contact with the layer to dislocate a third portion of the first nanoparticles and fourth portion of the second nanoparticles formed on the mask and leave fifth portion of first nanoparticles and sixth portion of the second nanoparticles on the layer.

17. The method of claim 16, wherein the third opening is smaller than the first opening and wherein the second opening is smaller than the fourth opening.

18. The method of claim 16, wherein the first nanoparticles enter through the third opening and wherein a seventh portion of the first nanoparticles is deposited on an upper surface of the shadow mask and wherein the second nanoparticles enter through the fourth opening and wherein an eighth portion of the second nanoparticles is deposited on the upper surface of the shadow mask.

19. The method of claim 16, wherein the first opening and the second opening are separated by a lateral distance of at least 1 micron.

20. The method of claim 16, wherein the first nanoparticles comprise one of gold, silver, copper, or platinum nanoparticles and the second nanoparticles comprise one of gold, silver, copper, or platinum nanoparticles.
